(19) United States
(12) Patent Application Publication
(10) Pub. No.: US 2026/0343941 A1
(43) Pub. Date: Oct. 29, 2026

(54) SEMICONDUCTOR TRANSISTOR DEVICE AND METHOD OF MANUFACTURING THE SAME

(71) Applicant: Infineon Technologies AG, Neubiberg (DE)

(72) Inventors: Kyrylo GREBEN, Villach (AT); Roman ROTH, Sattendorf (AT); Judith Veronika RADACHER, Klagenfurt am Wörthersee (AT)

(21) Appl. No.: 19/638,169

(22) Filed: Apr. 3, 2026

(30) Foreign Application Priority Data
Apr. 3, 2025 (DE) 102025113041.8

(51) Int. Cl. H10D 30/66; H10D 30/01; H10D 62/832; H10W 20/00; H10W 20/41; H10W 20/44; H10W 20/48

(52) U.S. Cl. CPC H10D 30/668; H10D 30/0297; H10W 20/033; H10W 20/047; H10W 20/054; H10W 20/435; H10W 20/4405; H10W 20/4424; H10W 20/48; H10D 62/8325

(57) ABSTRACT

The present application relates to a semiconductor transistor device, comprising: a semiconductor body, e.g. silicon carbide (SiC) semiconductor body; an insulating layer on a first side of the semiconductor body; a metallization on the insulating layer; wherein the metallization comprises a barrier layer and an upper layer arranged on the barrier layer, wherein a contact hole intersects the insulating layer, the contact hole having a width w, wherein the barrier layer has a thickness t which is at least half the width w of the contact hole, t≥w/2.

### RELATED APPLICATION

This application claims priority to German Patent Application No. 102025113041.8, filed on Apr. 3, 2025, entitled “SEMICONDUCTOR TRANSISTOR DEVICE AND METHOD OF MANUFACTURING THE SAME”, which is incorporated by reference herein in its entirety.

### TECHNICAL FIELD

The present disclosure relates to a semiconductor transistor device and to a method of manufacturing a semiconductor transistor device.

### BACKGROUND

The semiconductor transistor device may comprise a semiconductor body, on which an insulating layer and a metallization may be arranged. The metallization can for instance allow for a wiring of a device structure in the semiconductor body. The insulating layer may define a contact hole or contact holes, where an electrical contact is formed, e.g. between the metallization and the semiconductor body.

### SUMMARY

Embodiments of the present application aim at providing an advantageous semiconductor transistor device.

In an embodiment, the semiconductor transistor device comprises a semiconductor body, an insulating layer on a first side of the semiconductor body and a metallization on the insulating layer. The metallization comprises a barrier layer and an upper layer arranged on the barrier layer. With reference to a lateral width w of a contact hole intersecting the insulating layer, the barrier layer has a thickness t, wherein the thickness t is at least half the width w of the contact hole, t≥w/2. This means, the barrier layer may be chosen to have a minimum thickness which depends on the contact hole width, i.e. increases with increasing contact hole width.

Assuring a respective minimum thickness of the barrier layer can for instance be advantageous as to a filling of the contact hole, e.g. allow the contact hole to be completely filled by the barrier layer. This may reduce a topography at the upper side or surface of the barrier layer, which in turn can reduce the risk of a void or pinhole formation in the subsequently deposited upper layer of the metallization. In other words, providing a thickness t≥w/2 may assist or assure that the barrier layer grows together and fills the contact hole.

Further embodiments and features are provided in the claims and throughout this disclosure. Therein, the individual features shall be disclosed independently of a specific claim category, the disclosure relates to apparatus and device aspects but also to method and use aspects. If for instance a device manufactured in a specific way is described, this is also a disclosure of a respective manufacturing process, and vice versa. In general words, embodiments of the present application aim at filling a contact hole in an insulating layer with a barrier layer, the thickness of the barrier layer being at least half the width of the contact hole.

The insulating layer may be arranged on a first side of the semiconductor body, which may also be referred to as a “frontside”. The contact hole intersects the insulating layer, i.e. forms a through-hole. In other words, the contact hole may extend the entire way between an upper surface of the insulating layer and a vertically opposite lower surface of the insulating layer. The vertical direction may run essentially perpendicular to lateral directions, an extension of the semiconductor body in the vertical direction being for instance small compared to its extension in the lateral directions. Laterally, the area of the semiconductor body or die may be taken.

The width w of the contact hole may be taken in a lateral direction, in which the contact hole has its smallest lateral extension. This lateral direction may also be referred to as “transverse direction”. In a lateral direction perpendicular to the transverse direction, the contact hole can for instance have an elongated extension, and this direction may be referred to as “length direction”. Considering a device structure formed in the semiconductor body and comprising a plurality of device cells, these device cells can for instance have a translational symmetry with respect to the transverse direction.

In detail, the lateral width w may be taken on a vertical position between the lower and the upper end of the contact hole, e.g. at half the height of the contact hole. In other words, the width w may be taken at half the thickness of the insulating layer.

Generally, when reference is made to an arrangement of a layer or entity “on” another layer or entity, e.g. an arrangement of the insulating layer on the semiconductor body and/or of the metallization on the insulating layer, this does not necessarily imply an arrangement directly adjacent to this layer or entity. In other words, an additional layer may be arranged in between the insulating layer and the semiconductor body and/or in between the metallization and the insulating layer. The additional layer may for instance serve as an adhesion promoter and/or etch stop layer. It can for instance have a thickness of not more than 30 nm, 20 nm, 15 nm or 6 nm, a possible lower limit being for instance 3 nm. Summarized in other words, an arrangement “on” can mean a certain distance, e.g. a comparably small distance of no more than 100 nm, 50 nm, 30 nm, 20 nm 15 nm or 6 nm, or an arrangement “directly on”.

The barrier layer may comprise one or a plurality of sublayers, a respective sublayer comprising for instance at least one of Ti, W, or N. Vice versa, the upper layer can for instance comprise aluminum and/or copper, as discussed in further detail below. The thickness t of the barrier layer may be taken in the vertical direction, e.g. on the insulating layer, i.e. aside the contact hole. In other words, the thickness t may be taken from an upper surface of the insulating layer to an upper surface of the barrier layer and/or to a lower surface of the upper metallization layer (e.g. to a lower surface of an aluminum and/or copper layer).

In case of an insulating layer provided with a plurality of contact holes, the criterion t≥w/2 can for instance be fulfilled for each of the contact holes. The contact holes may be arranged with a translational symmetry in the transverse direction, e.g. with the same pitch like device cells in the semiconductor body. With the contact hole or holes, the insulating layer may define a contact structure between the metallization and the semiconductor body, e.g. serve as an interlayer dielectric. By way of example, the insulating layer may have a total thickness with lower limits of at least 0.1 μm, 0.2 μm, 0.3 μm or 0.4 μm, upper limits being for instance at most 3 μm, 2 μm or 1.5 μm.

The semiconductor body may comprise a semiconductor substrate, for instance in combination with one or a plurality of epitaxial layers thereon. Embodiments of the present application relate to a semiconductor body made of silicon carbide (SiC). This can for example allow for comparably high voltages in operation of the device or device structure.

The semiconductor transistor device may comprise a first load terminal and a second load terminal, for instance, the first load terminal being arranged at the first side of the semiconductor body and the second load terminal being arranged at the vertically opposite second side of the semiconductor body. The transistor device may be a field effect transistor (FET), the first load terminal being for example a source region and the second load terminal being a drain region. In addition, a body region may be arranged in the semiconductor body, e.g. below the source region formed at the first side of the semiconductor body and/or above the drain region formed at the second side of the semiconductor body. Optionally, the transistor device can comprise a drift region between the body and drain region, e.g. made of the same doping type but with a lower doping concentration than the drain region. Independently of these details, the contact can for instance be arranged in an active area of a chip or die, e.g. above the device structure (laterally inside of an edge termination).

In general, the metallization at the bottom of the contact hole may make an electrical contact to an entity embedded into the semiconductor body, e.g. to an electrode made of conductive material (e.g. polysilicon or metal). In an embodiment, however, the metallization makes an electrical contact to a region formed in the semiconductor body, e.g. to a doped region. Referring to a transistor device as discussed above, the metallization can for instance contact the first load terminal, e.g. source region, in the contact hole. Alternatively or in addition, it may contact an adversely doped region, e.g. a body or diode region of the device.

In an embodiment, a side wall of the contact hole, as viewed in a vertical cross-section, forms an angle δ of at most 10° to the vertical direction (which lies perpendicular to the lateral directions, see above). In other words, the side wall or walls of the contact hole have a comparably steep orientation, which can for instance reduce a variation between a contact opening width at the bottom and at the top of the contact hole. The reduced variation of the contact hole width may reduce or prevent a “hilly” topography, i.e. enable a rather flat topography which prevents the void or pinhole formation.

In detail, the angle δ may be taken as smallest angle between the vertical direction and the side wall of the contact hole as seen in the vertical cross-section. By way of example, the angle δ may be taken between the vertical direction and a straight line fitted into the side wall of the contact hole as seen in the vertical cross-section (linear fit), for instance in case of a curved or bulged side wall. In an embodiment, however, the side walls form a straight line as viewed in the vertical cross-section. Independently of these details, the sectional plane can, for instance, lie parallel to a translational symmetry direction of the device cells and/or parallel to the transverse direction.

In an embodiment, the width of the contact hole is at least 0.1 μm, further lower limits being for instance at least 0.2 μm, 0.3 μm, 0.4 μm or 0.5 μm. Upper limits of the contact hole width can for instance be at most 10 μm, 8 μm, 6 μm or 4 μm.

In an embodiment, an upper surface of the barrier layer has a roughness of at least 10 nm, further lower limits being for instance at least 15 nm or 20 nm. In other words, a certain roughness may be allowed, the upper surface can for instance be non-planarized, e.g. be not planarized by chemical-mechanical-polishing (CMP). In detail, the roughness can for instance be measured as an arithmetic mean height (Sa). In case of a device structure comprising elongated trench structures, e.g. elongated gate trenches, the measurement can for instance be performed in parallel to the trenches (to not capture a possible topography caused by the trenches). Independently of these details, an upper limit of the roughness can for instance be at most 300 nm.

In an embodiment, the barrier layer fills the contact hole over the entire height of the contact hole. As viewed for instance in a vertical cross-section perpendicular to the side wall of the contact hole, the upper surface of the barrier layer is for example arranged at or above the upper end of the contact hole. This may apply over the entire width. In other words, the upper surface of the barrier layer may be arranged above a surface plane which contains the upper surface of the insulating layer. As viewed in the vertical cross-section, the surface plane may be a straight line perpendicular to the vertical direction, wherein the straight line is a tangent to the upper surface of the insulating layer.

In other words, the surface plane is not the actual surface of the insulating layer, instead it is a mathematical plane fitted into the upper surface of the insulating layer. Consequently, the surface plane extends across the contact hole and can for instance be used to describe or measure the filling height, e.g. in the middle of the contact hole (at a lateral position centrally between its side walls). In an embodiment, a portion of the barrier layer above the contact hole has, e.g. taken on the central position in the middle, a thickness tₕ of at least 20 nm, further lower limits being for instance at least 50 nm, 80 nm or 100 nm. By way of example, upper limits may be at most 5 μm, 4 μm, 3 μm, or 2 μm.

In an embodiment, the thickness t of the barrier layer, e.g. taken aside the contact hole on the insulating layer (see above), is at least 20 nm, further lower limits being for instance at least 50 nm, 100 nm or 200 nm. By way of example, upper limits may be at most 5 μm, 4 μm, 3 μm, or 2 μm.

In an embodiment, the barrier layer comprises at least one tungsten-based layer. The tungsten-based layer may consist of tungsten, i.e. be a W layer, or comprise W, e.g. be a TiW layer. In other words, the barrier layer may comprise at least one of W or TiW. By way of example, the barrier layer may comprise at least a W layer, e.g. in combination with a TiW layer on the W layer. As discussed above, the barrier layer may be a single layer or a stack made of a plurality of (sub)layers. Alternatively or in addition to the tungsten-based layer, it may comprise a titanium-based layer, e.g. a Ti and/or TiN layer, and/or a tantalum-based layer, e.g. a Ta and/or a TaN layer. The titanium-based layer(s) and/or the tantalum-based layer(s) can for instance be arranged below the tungsten-based layer(s). In general, the barrier layer may comprise a nitrogen-based layer.

In an embodiment, the upper layer of the metallization is or comprises a sputter-deposited layer, e.g. a sputtered Cu or sputtered AlCu layer. The sputter-deposited layer can for instance have a thickness of at least 0.5 μm, 1 μm or 1.5 μm. However, alternative materials are conceivable in general, e.g. a Ni or NiV layer. Providing the upper layer as a sputter-deposited layer can for instance be advantageous as to a throughput. Vice versa, the aspect ratio discussed above can reduce or prevent a void or pinhole formation, e.g. when the upper layer is sputter-deposited. Reducing a void formation based on topography considerations can also enable reduced deposition temperatures (which may be economically advantageous and/or reduce a risk of cross reactions).

In an embodiment, the upper layer is or comprises an aluminum layer or a copper layer. The aluminum layer can for instance consist of aluminum or of aluminum and copper, e.g. be an Al layer or AlCu layer. The copper layer may comprise or consist of copper, e.g. be a Cu layer. The upper layer can for instance have a total thickness of at least 2 μm and/or most 30 μm. The upper layer may be one single layer, e.g. sputter-deposited copper layer. Alternatively, the upper layer may be a stack comprising a plurality of layers, e.g. a sputter-deposited seed layer and one or a plurality of bath-deposited layers on top. In other words, the upper layer of the metallization may comprise a plated layer or layers. In case of a stack, the aforementioned thickness range applies for the entire stack. By way of example, the thickness of the upper layer may be taken vertically from the upper surface of the barrier layer to an uppermost surface of the metallization.

An additional layer or layers may be arranged on the upper layer. In other words, the upper layer is not necessarily the uppermost layer of the metallization. The additional layer(s) can for instance comprise one of nickel, phosphor and palladium, e.g. a NiP layer and a Pd layer thereon. Optionally, a gold layer may be arranged on top.

In an embodiment, the insulating layer comprises a phosphosilicate glass (PSG) or borophosphosilicate glass (BPSG) layer with a boron content of at most 2.9% (percentage by mass, i.e. wt. %). A further upper limit can for instance be at most 2.6%, a possible lower limit of the boron content being for example at least 1%. Providing a PSG or BPSG layer can for instance be advantageous as to a reflow behavior, e.g. avoid a rounding at the upper edge and reduce the topography.

Alternatively or in addition, the insulating layer may comprise a phosphosilicate glass (PSG) or borophosphosilicate glass (BPSG) layer with a phosphorus content of at most 5%, further upper limits being for instance at most 4% or 3%. A possible lower limit can for example be 1%. Again, this relates to percentage by mass, i.e. wt. %.

In an embodiment, a method of manufacturing a semiconductor transistor device comprises:
i. forming an insulating layer on a first side of a semiconductor body;
ii. etching a contact hole which intersects the insulating layer and has a width w;
iii. forming a metallization on the insulating layer.

The metallization comprises a barrier layer, it can be a single barrier layer or a stack as discussed above. The barrier layer has a thickness t≥w/2. As to further embodiments and details, reference is also made to the description above.

In an embodiment, the contact hole is etched anisotropically in step ii, e.g. over the entire depth of the contact hole. In other words, solely an anisotropic etch is applied for the contact hole, which can for instance allow for comparably steep side walls (reduced topography, see above).

In an embodiment, after etching the contact hole and prior to forming the barrier layer, a transition metal layer is deposited into the contact hole and is reacted to form a silicide in the contact hole. The transition metal may react with the substrate material, e.g. silicon, at the bottom of the contact hole, e.g. in an anneal step, so that a transition metal silicide is formed there. However, it does for instance not react with oxide, so that the transition metal remains on the insulating layer. The non-reacted transition metal, i.e. remaining transition metal, may be removed subsequently. The transition metal may be or comprise a transition metal, e.g. Ni, NiAl, NiSi, TiAl or the like.

Such a self-aligned silicidation may allow contact formation also for comparably steep flanks of the contact hole [see above]. For comparison, a lift-of process in which the transition metal would be deposited onto a photoresist for a removal from the insulating layer, would require an access to the photoresist for the lift-of chemistry, which is achieved with a certain under etch at the side wall of the contact hole.

### BRIEF DESCRIPTION OF THE DRAWINGS

Below, the semiconductor transistor device and method of manufacturing are explained in further detail by means of exemplary embodiments. Therein, the individual features can also be relevant in a different combination.

FIGS. 1a,b show cross-sectional views of a semiconductor transistor device;

FIG. 2 illustrates a detailed view of a contact hole in an insulating layer, filled by a barrier layer;

FIG. 3 shows another detailed view of a contact hole;

FIGS. 4 a,b shows schematic views to illustrate different topographies;

FIG. 5 summarizes some manufacturing steps in a flow diagram.

### DETAILED DESCRIPTION

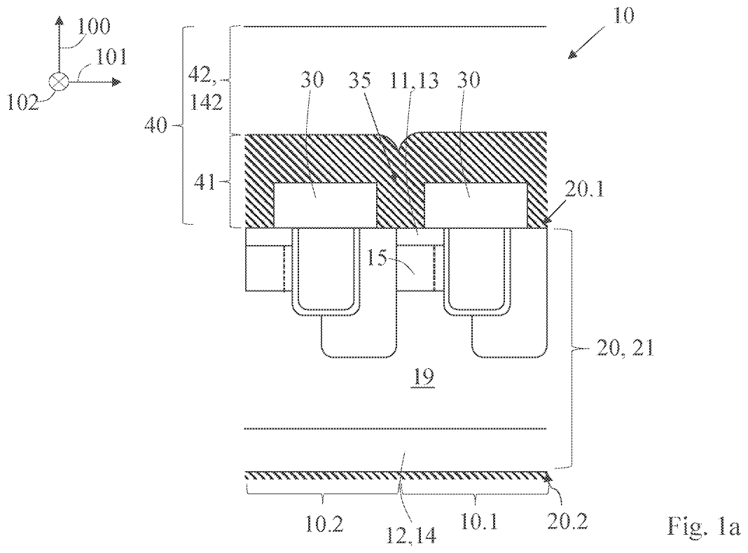

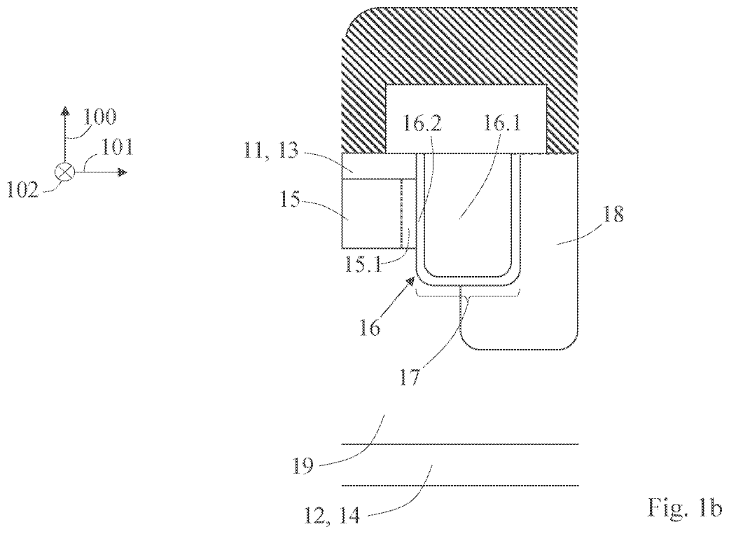

FIG. 1a shows a semiconductor transistor device 10 in a vertical cross-section, wherein the sectional plane lies parallel to a vertical direction 100 and to a transverse direction 101. The device 10 comprises a plurality of device cells 10.1, 10.2, wherein a portion of a first device cell 10.1 is shown with further details in FIG. 1b. The following description refers to FIG. 1a and FIG. 1b. The device cells 10.1, 10.2 are formed in a semiconductor body 20, which is a silicon carbide (SiC) semiconductor body 21 in the example shown.

On a first side 20.1 of the semiconductor body 20, an insulating layer 30 is arranged, wherein a metallization 40 is formed on the insulating layer 30. The metallization 40 comprises a barrier layer 41 and an upper layer 42, e.g. copper layer 142. These layers, which may respectively comprise a stack of layers, are not shown to scale in this schematic drawing. In a contact hole 35, which intersects the insulating layer 30, the metallization 40 makes an electrical contact to the semiconductor body 20. In a length direction 102, i.e. perpendicular to the drawing plane, the contact hole has an elongated extension.

The device 10 is a vertical device, which comprises a first load terminal 11 at the first side 20.1 of the semiconductor body 20 and a second load terminal 12 at the second side 20.2. In the example shown, the first load terminal 11 is a source region 13, and the second load terminal 12 is a drain region 14. Below the source region 13, a body region 15 is arranged, in which a channel region 15.1 is formed, see FIG. 1b.

Aside the channel region 15.1, a gate region 16 is arranged. In the example shown, it is arranged laterally aside the channel region 15.1 in a gate trench 17. The gate region 16 comprises a gate electrode 16.1 and a gate dielectric 16.2, via which the gate electrode 16.1 capacitively couples to the channel region 15.1. At the opposite side wall of the gate trench 17, a diode region 18 is formed, e.g. having the same doping type like the body region 15. Below the body region 15 and the diode region 18, a drift region 19 is arranged, e.g. made of the same doping type like the drain region 14. In the example shown, the source region 13, drift region 19 and drain region 14 are n-doped, whereas the body region 15 and diode region 18 are p-doped.

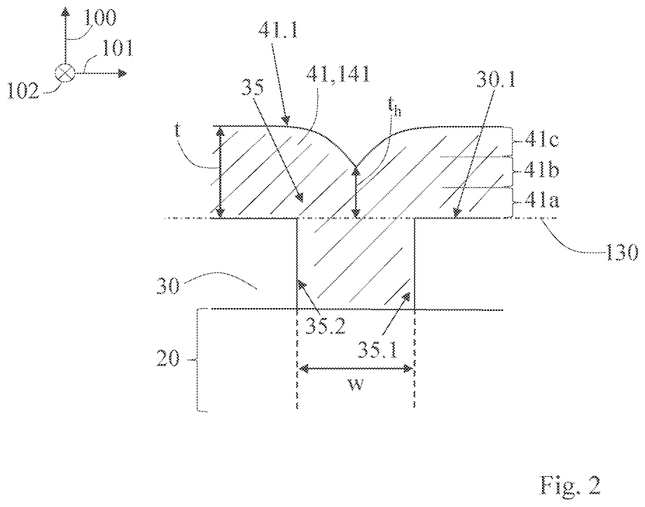

FIG. 2 illustrates the contact hole 35 and the barrier layer 41 in further detail. With respect to the transverse direction 101, the contact hole 35 is defined by the side walls 35.1, 35.2 in the insulating layer 30. Referring to a width w of the contact hole 35, the barrier layer 41 has a thickness t which is at least half the width, t≥w/2. Providing this aspect ratio may allow the contact hole 35 to be filled by the barrier layer 41 completely, which reduces a topography at the upper surface 41.1 of the barrier layer 41. Referring to a surface plane 130, which is fitted into the upper surface 30.1 of the insulating layer 30, the portion of the barrier layer 41 above the contact hole 35 has a thickness tₕ, e.g. of a few tens or hundreds of nanometers. In other words, the barrier layer 41 fills the contact hole 35 completely and extends also above.

The barrier layer 41 can be or comprise a tungsten-based layer 141. The barrier layer 41 may be a stack made of a plurality of layers 41a-41c, as indicated schematically in the example shown.

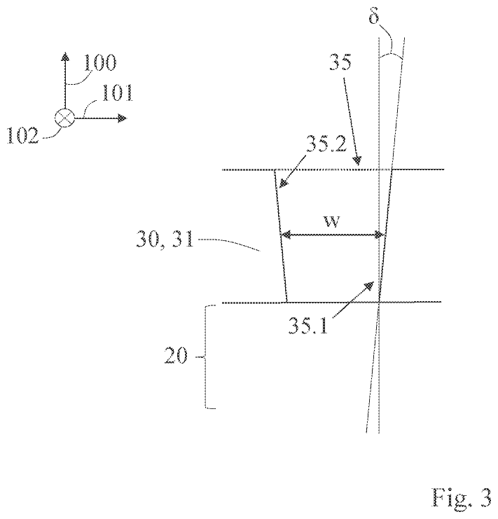

FIG. 3 shows another detailed view of the contact hole 35 in the insulating layer 30, wherein the barrier layer is not depicted here. The sectional plane lies perpendicular to the side walls 35.1, 35.2 and parallel to the vertical direction 100. The side walls 35.1, 35.2 are respectively at an angle δ to the vertical direction 100. The angle δ may be at most 10°, e.g. around 5° in the example shown. As discussed and illustrated above, it may also become zero, so that the side walls 35.1, 35.2 lie parallel to the vertical direction 100. In case of inclined side walls 35.1, 35.2, the width w is taken at half the height of the contact hole 35.

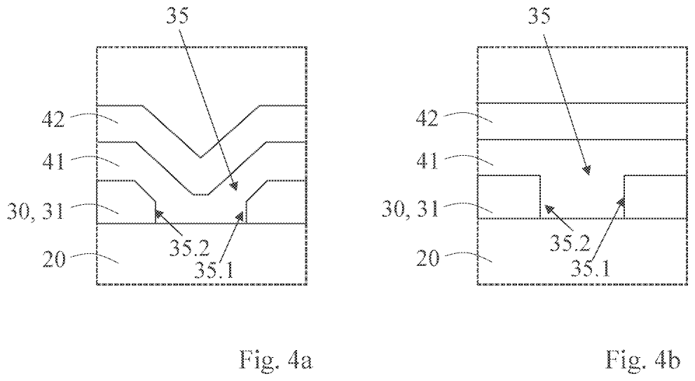

The insulating layer 30 may be or comprise a PSG or BPSG layer 31, e.g. as an uppermost layer in case that the insulating layer is a layer stack. This can for instance reduce a rounding at the upper edge of the side walls 35.1, 35.2. FIGS. 4 a, b illustrate a schematic comparison between side walls 35.1, 35.2 with a rounding (FIG. 4a) and without a rounding (FIG. 4b). Providing comparably steep side walls 35.1, 35.2 over the entire height of the contact hole 35 can reduce a topography in the subsequent layer stack, e.g. in the barrier layer 41. This can reduce or prevent a void formation in the upper layer 42, e.g. at a possibly critical location centrally above the contact hole 35.

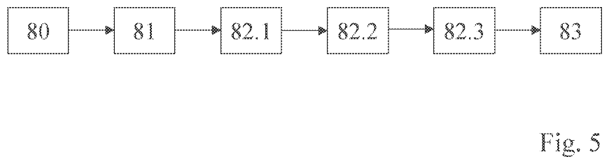

FIG. 5 summarizes some manufacturing steps in a flow diagram. Manufacturing the semiconductor transistor device may comprise forming 80 an insulating layer on a semiconductor body. A contact hole may be etched 81 before a metallization is formed 83 on the insulating layer. Optionally, a silicidation can be implemented after the contact hole has been etched 81, e.g. by depositing 82.1 a transition metal layer into the contact hole and onto the insulating layer, reacting 82.2 the transition metal to form a transition metal silicide, and removing 82.3 the non-reacted transition metal.

1. A semiconductor transistor device, comprising:
a semiconductor body;
an insulating layer on a first side of the semiconductor body; and
a metallization on the insulating layer;
wherein the metallization comprises a barrier layer and an upper layer arranged on the barrier layer,
wherein a contact hole intersects the insulating layer, the contact hole having a width w,
wherein the barrier layer has a thickness t which is at least half the width w of the contact hole, t≥w/2.

2. The semiconductor transistor device of claim 1, wherein a side wall of the contact hole, as viewed in a vertical cross-section perpendicular to the side wall of the contact hole, forms an angle δ of at most 10° to a vertical direction.

3. The semiconductor transistor device of claim 1, wherein the width w of the contact hole is at least one of at least 0.1 μm or at most 10 μm.

4. The semiconductor transistor device of claim 1, wherein an upper surface of the barrier layer has a roughness of at least 10 nm.

5. The semiconductor transistor device of claim 1, wherein the barrier layer, as viewed in a vertical cross-section perpendicular to a side wall of the contact hole, fills the contact hole over its entire height.

6. The semiconductor transistor device of claim 5, wherein a part of the barrier layer above the contact hole has a thickness tₕ of at least 20 nm taken from a surface plane which contains an upper surface of the insulating layer.

7. The semiconductor transistor device of claim 6, wherein the thickness t of the barrier layer is at least one of at least 20 nm or at most 5 μm.

8. The semiconductor transistor device of claim 1, wherein the barrier layer comprises at least one of a tungsten-based layer or a titanium-based layer.

9. The semiconductor transistor device of claim 1, wherein the upper layer comprises a sputter-deposited layer.

10. The semiconductor transistor device of claim 1, wherein the upper layer comprises at least one of an aluminum layer or a copper layer.

11. The semiconductor transistor device of claim 1, wherein the insulating layer comprises at least one of a phosphosilicate (PSG) layer or a borophosphosilicate (BPSG) layer with a boron content of at most 2.9%.

12. The semiconductor transistor device of claim 1, wherein the insulating layer comprises at least one of a phosphosilicate (PSG) or a borophosphosilicate (BPSG) layer with a phosphorus content of at most 5%.

13. A method of manufacturing the semiconductor transistor device of claim 1, comprising:
forming the insulating layer on the first side of the semiconductor body;
etching the contact hole which intersects the insulating layer and has the width w; and
forming the metallization on the insulating layer.

14. The method of claim 13, wherein the contact hole is etched anisotropically over its entire depth.

15. The method of claim 13, comprising:
depositing a transition metal layer into the contact hole and onto the insulating layer;
reacting the transition metal to form a silicide in the contact hole; and
removing remaining transition metal.

16. A method of manufacturing a semiconductor transistor device, comprising:
forming an insulating layer on a first side of a semiconductor body;
etching a contact hole which intersects the insulating layer and has a width w; and
forming a metallization on the insulating layer;
wherein the metallization comprises a barrier layer,
and wherein the barrier layer has a thickness t which is at least half the width w of the contact hole, t≥w/2.

17. The method of claim 16, comprising:
depositing a transition metal layer into the contact hole and onto the insulating layer.

18. The method of claim 17, comprising:
reacting the transition metal to form a silicide in the contact hole.

19. The method of claim 18, comprising:
removing remaining transition metal.

20. A semiconductor transistor device, comprising:
a semiconductor body;
an insulating layer on a first side of the semiconductor body; and
a metallization on the insulating layer;
wherein the metallization comprises a barrier layer,
wherein a contact hole intersects the insulating layer, the contact hole having a width w,
wherein the barrier layer has a thickness t which is at least half the width w of the contact hole, t≥w/2.
